(19) United States
(12) Patent Application Publication
(10) Pub. No.: US 2017/0110463 A1
(43) Pub. Date: Apr. 20, 2017

(54) Imprinted Memory

(71) Applicant: Guobiao ZHANG, Corvallis, OR (US)

(72) Inventor: Guobiao ZHANG, Corvallis, OR (US)

(73) Assignee: ChengDu HaiCun IP Technology LLC, ChengDu (CN)

(21) Appl. No.: 15/390,498

(22) Filed: Dec. 24, 2016

Related U.S. Application Data
(63) Continuation-in-part of application No. 14/745,377, filed on Jun. 20, 2015.
Application No. 14/745,377 is a continuation-in-part of application No. 13/602,095, filed on Aug. 31, 2012, now abandoned.
(60) Provisional application No. 61/529,919, filed on Sep. 1, 2011.

(51) Int. Cl. H01L 27/112

(52) U.S. Cl. CPC H01L 27/1128; H01L 27/11253

(57) ABSTRACT

Although photolithography is the preferred pattern-transfer method for even the 10 nm electrically-programmable memory (EPM, which comprises only periodic patterns), imprint-lithography is the preferred method to form the sub-25 nm printed memory (which comprises at least one non-periodic data-pattern). Accordingly, the present invention discloses an imprinted memory.

### CROSS-REFERENCE TO RELATED APPLICATIONS

This is a continuation-in-part of application “Imprinted Memory”, application Ser. No. 14/745,377, filed Jun. 20, 2015, which is a continuation-in-part of application “Imprinted Memory”, application Ser. No. 13/602,095, filed Aug. 31, 2012, which claims benefit of a provisional application “Three-Dimensional Printed Memory”, application Ser. No. 61/529,919, filed Sep. 1, 2011.

### BACKGROUND

1. Technical Field of the Invention

The present invention relates to the field of integrated circuit, and more particularly to mask-programmed read-only memory (mask-ROM).

2. Prior Art

Printed memory is a memory whose data is recorded by a printing method. It comprises at least a data-coding layer which is different for the memory cells storing different data. The pattern of the data-coding layer is referred to as data-pattern, which is non-periodic in nature (referring to U.S. Patent Application “Three-Dimensional Printed Memory”, Ser. No. 13/570,216, filed Aug. 8, 2012). A common printed memory is mask-programmed read-only memory (mask-ROM), whose data-recording method is photo-lithography.

U.S. Pat. No. 6,903,427 issued to Zhang on Jun. 7, 2005 discloses a mask-ROM based on nf-opening mask. As illustrated in FIG. 1, this mask-ROM comprises a plurality of top address lines (e.g. 2a-2d), bottom address lines (e.g. 1a-1d) and memory cells (e.g. 5aa-5dd). Its data-coding layer is an insulating dielectric 87 between the top and bottom address lines. Absence or existence of a data-opening (e.g. 7aa, 7ad) in the insulating dielectric 87 (more clearly shown in FIG. 2C) indicates the state of a memory cell. For example, absence of a data-opening at the memory cell 5ab represents ‘0’, while existence of a data-opening 7aa at the memory cell 5aa represents ‘1’. Apparently, the data-opening pattern is a data-pattern and it is non-periodic in nature. On the other hand, other patterns in the mask-ROM, e.g. those of the top and bottom address lines, are periodic. Note that, in an nf-opening mask-ROM, the data-opening dimension F could be twice as much as the address-line dimension f (i.e. F=2 f); and, f is generally used as an indicator of technology node, e.g. f=25 nm generally means the 25 nm-node.

It is well known that periodic patterns are much easier to scale to the sub-25 nm nodes than non-periodic patterns. As a result, although the state-of-the-art electrically-programmable memory (EPM, which only comprises periodic patterns) has advanced to the 10 nm-nodes, the state-of-the-art mask-ROM (which comprises at least one non-periodic pattern) lags behind at the 25 nm-node, because the dimension of its data-openings (whose pattern is non-periodic) cannot be scaled down with the address lines (whose pattern is periodic) and remains ˜50 nm (even though the address-line dimension in the EPM has been scaled down to the 10 nm). For example, Ye et al. discloses a mask-ROM whose contacts are 54 nm in dimension (“A 40-nm 16-Mb Contact-Programming Mask-ROM Using Dual Trench Isolation Diode Bitcell”, IEEE Transactions on Very Large Scale Integration (VLSI) Systems, Vol. 24, No. 4, April 2016, FIG. 1a). It is highly desired for the mask-ROM to catch up with the EPM in terms of technology nodes.

To scale mask-ROM further to below the 25 nm-node, new pattern-transfer method needs to be developed for the sub-50 nm non-periodic data-openings. The state-of-the-art pattern-transfer method includes photolithography and nanoimprint lithography (NIL). Photolithography uses light to transfer a geometric pattern from a photomask to parts of a thin film or the bulk of a substrate. NIL creates patterns by mechanical deformation of imprint resist and subsequent processes. In the past, NIL was developed with an initial goal to replace the conventional photolithography at the sub-micron nodes. However, with the advent of resolution-enhancement techniques (RET), photolithography remains as the dominant pattern-transfer method, even for the sub-25 nm-nodes.

U.S. Pat. No. 7,804,716 issued to Kwak et al. on Sep. 28, 2010 discloses a flash memory device formed using multiple-patterning technique (MPT, which is a form of RET) such as double-patterning. During double-patterning, a pattern is divided into two parts, each of which may be processed conventionally, with the entire pattern combined at the end in the final layer. At present, 10 nm-class flash memory has been mass-produced using MPT. It is expected that the 7 nm-and-beyond flash memory will still use MPT. Being more mature than NIL, photolithography is the method of choice to transfer periodic two-dimensional (2D) shapes (i.e. single-stepped shapes, e.g. an opening, an island or a line).

Only in three-dimensional (3D) pattern transfer, NIL shows advantage over photolithography. U.S. Pat. No. 8,105,884 issued to Lee et al. on Jan. 31, 2012 discloses a cross-point memory which uses NIL to form 3D storage holes. It comprises a plurality of bottom electrodes, an insulating layer on the bottom electrodes, a plurality of storage holes through the insulating layer, a layer of memory resistor on the bottom and sidewalls of the storage holes, and a plurality of top electrodes covering the memory resistor. The storage holes have three-dimensional (3D) shapes (i.e. multi-stepped shapes, e.g. a cone shape, a cylindrical shape, a pyramidal shape, or an asymmetrically polygonal shape). Being more convenient to form 3D shapes, NIL is used to form the storage holes in the cross-point memory.

The memories disclosed in Kwak (i.e. the flash memory) and Lee (i.e. the cross-point memory) are both EPM. Comprising no non-periodic pattern, EPM comprises only periodic patterns. In contrast, mask-ROM comprises at least one non-periodic data-pattern. Unfortunately, non-periodic pattern transfer is much more difficult than periodic pattern transfer. Neither prior art (Kwak or Lee) teaches any non-periodic pattern-transfer method for the sub-25 nm-nodes.

### OBJECTS AND ADVANTAGES

It is a principle object of the present invention to provide a printed memory which catches up with electrically-programmable memory (EPM) in terms of technology nodes.

It is a further object of the present invention to provide a printed memory whose data-pattern dimension is less than 50 nm.

It is a further object of the present invention to provide a sub-50 nm non-periodic pattern-transfer method.

In accordance with these and other objects of the present invention, an imprinted memory is disclosed.

### SUMMARY OF THE INVENTION

Because electrically-programmable memory (EPM) comprises only periodic patterns for which photolithography has advantage over nanoimprint lithography (NIL), photolithography is the method of choice for the sub-25 nm EPM. Compared with EPM, mask-ROM comprises at least one extra data-pattern, which is non-periodic. For non-periodic patterns, photolithography becomes cumbersome because periodic patterns are much easier to scale down than non-periodic patterns. Since it is difficult for photolithography to form sub-50 nm non-periodic data-pattern, mask-ROM (currently at the 25 nm-node) lags behind EPM (currently at the 10 nm-node). It is highly desired for mask-ROM to catch up with EPM in terms of technology nodes.

To scale mask-ROM further to below the 25 nm-node, the present invention discloses an imprinted memory. It uses imprint-lithography to form sub-50 nm non-periodic data-pattern. The imprint-lithography transfers the pattern from its data-template to a data-coding layer by mechanical deformation of imprint resist and subsequent processes. Here, the data-template is the template (also referred to as stamp, master or mold) that is used to transfer data-pattern to the data-coding layer. Imprint-lithography includes thermoplastic nanoimprint lithography (NIL), photo-NIL, resist-free direct thermal-NIL, electro-chemical NIL, laser-assisted direct imprint lithography. Imprint-lithography may use a full-wafer imprint scheme, or a step-and-repeat imprint scheme.

In imprint-lithography, the target pattern (i.e. the pattern formed in the data-coding layer) is an exact 1:1 copy of the source pattern (i.e. the pattern on the data-template). Because imprint-lithography is a mechanical process and would not be interfered by any optical effects (e.g. optical diffraction or optical distortion), periodicity of the target pattern has no effect on the source pattern. That means that imprint-lithography makes as good non-periodic pattern-transfer as periodic pattern-transfer. Thus, the data-template doses not need to use any RET and can readily transfer sub-50 nm non-periodic data-pattern to the data-coding layer. In sum, imprint-lithography is a viable method of data recording for the sub-25 nm printed memory.

### BRIEF DESCRIPTION OF THE DRAWINGS

FIG. 1 illustrates a data-pattern in a mask-ROM.

FIGS. 2A-2C discloses processing steps of a preferred imprint-lithography.

FIGS. 3A-3B are top views of the data-pattern on two preferred data-templates.

FIG. 4 illustrates a preferred three-dimensional imprinted memory (3D-iP).

It should be noted that all the drawings are schematic and not drawn to scale. Relative dimensions and proportions of parts of the device structures in the figures have been shown exaggerated or reduced in size for the sake of clarity and convenience in the drawings. The same reference symbols are generally used to refer to corresponding or similar features in the different embodiments.

### DETAILED DESCRIPTION OF THE PREFERRED EMBODIMENTS

Those of ordinary skills in the art will realize that the following description of the present invention is illustrative only and is not intended to be in any way limiting. Other embodiments of the invention will readily suggest themselves to such skilled persons from an examination of the within disclosure.

The present invention discloses an imprinted memory. Because photolithography cannot be used to form the sub-50 nm non-periodic data-pattern, imprint-lithography is used. It creates pattern by mechanical deformation of imprint resist and subsequent processes (referring to Chou et al. “Imprint-lithography with 25-nanometer resolution”, Science, Vol. 272, No. 5258, pp. 85-87, 1996). Imprint-lithography includes thermoplastic-NIL, photo-NIL, resist-free direct thermal-NIL, electro-chemical NIL, laser-assisted direct imprint lithography. Imprint-lithography may use a full-wafer imprint scheme, or a step-and-repeat imprint scheme.

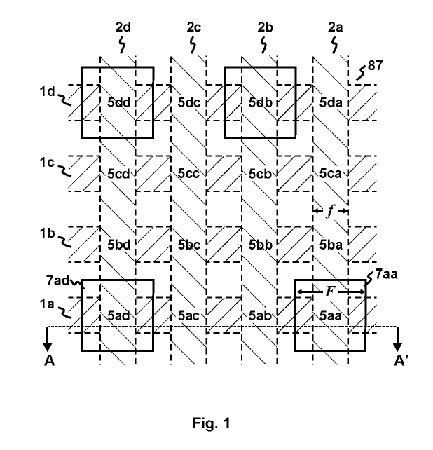

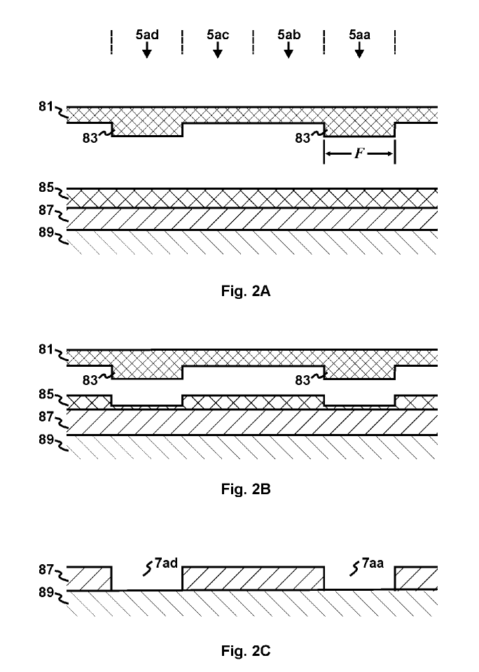

FIGS. 2A-2C discloses processing steps of a preferred imprint-lithography. These figures are the cross-sectional views along the cut-line AA′ of FIG. 1. These steps are used to physically record data for the memory of FIG. 1. This preferred imprint-lithography is thermoplastic-NIL. Its detailed processing steps are as follows. First of all, the data-coding layer (e.g. an insulating dielectric) 87 is formed on a bottom layer 89 (e.g. an address line). Then a thin layer of imprint resist (e.g. thermoplastic polymer) 85 is spin coated on the data-coding layer 87 (FIG. 2A). A template 81 is brought into contact with the imprint resist 85 and they are pressed together under certain pressure. When heated up above the glass transition temperature of the polymer, the pattern on the template 81 is pressed into the softened polymer film. After being cooled down, the template 81 is separated from the wafer (FIG. 2B). Finally, an etching process is carried out to transfer the pattern in the resist 85 to the data-coding layer 87 (FIG. 2C).

Another preferred imprint-lithography is photo-NIL. In the photo-NIL, a UV-curable liquid resist is applied to the data-coding layer. After the template and the substrate are pressed together, the resist is cured in the UV light and becomes solid. After template separation, a similar pattern transfer process can be used to transfer the pattern in resist onto the underneath material. Besides thermoplastic-NIL and photo-NIL, other imprint-lithography methods are well known in the art.

The template 81 has a predefined topological pattern. It comprises a plurality of islands 83, which protrudes out of a surface of the template. The dimension of these islands (i.e. data-pattern) is less than 50 nm. The absence or existence of an island at a location on the template determines on the state of the memory cell corresponding to this location. For example, if the location for a memory cell (e.g. 5ab) has no island, then this memory cell has no data-opening (FIG. 1) and is in state “0”; on the other hand, if the location for a memory cell (e.g. 5aa) has an island 83, then this memory cell has a data-opening (FIG. 1) and is in state “1”. Note that, after imprint-lithography, the shape of the imprint resist 85 is inverse to the shape of the template 81.

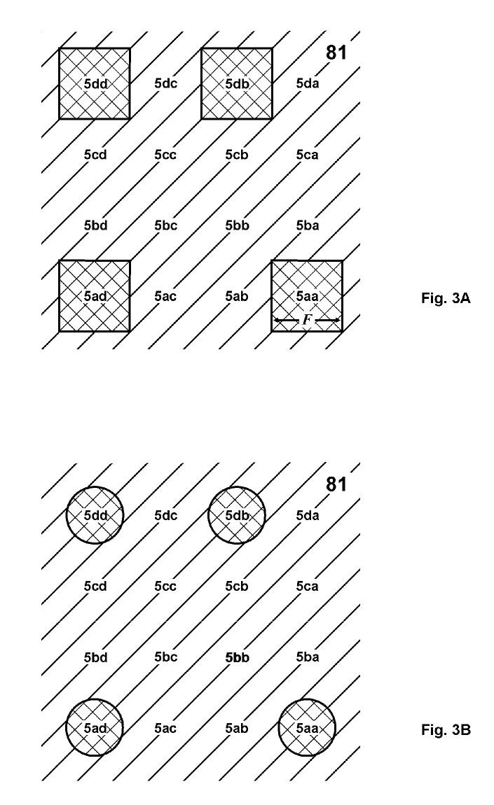

FIG. 3A illustrates the data-pattern on a preferred data-template 81. The minimum feature size F of its island (e.g. the one at the location 5aa) could be larger than, preferably twice as much as, the minimum feature size f of the imprinted memory, e.g. the minimum half-pitch (or, the width) of its address lines (referring to Zhang). Accordingly, the data-template 81 is also referred to as xf-template (with x>1, preferably ˜2). This can significantly lower the data-template cost. For example, a 25 nm imprinted memory can use a 50 nm data-template. In this preferred embodiment, the islands 83 have a rectangular shape.

FIG. 3B illustrates the data-pattern on another preferred data-template 81. Its island (e.g. the one at the location 5aa) has a circular cylinder shape. Alternatively, these islands could have a cone shape, a pyramidal shape, or an asymmetrically polygonal shape. These shapes can be easily formed by electron beams that directly write data onto the data-template 81. Note that the data-patterns in FIGS. 3A and 3B are non-periodic, whereas the storage-hole pattern in Lee is periodic.

In imprint-lithography, the target pattern (i.e. the pattern formed in the data-coding layer) is an exact 1:1 copy of the source pattern (i.e. the pattern on the data-template). Because imprint-lithography is a mechanical process and would not be interfered by any optical effects (e.g. optical diffraction or optical distortion), periodicity of the target pattern has no effect on the source pattern. That means that imprint-lithography makes as good non-periodic pattern-transfer as periodic pattern-transfer. Thus, the data-template doses not need to use any RET and can readily transfer sub-50 nm non-periodic data-pattern to the data-coding layer.

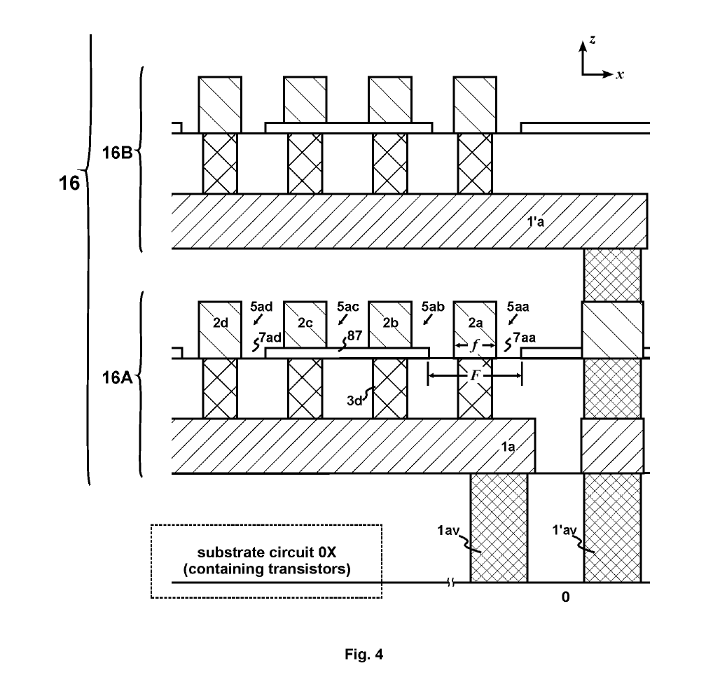

Imprint-lithography can be used in three-dimensional printed memory (3D-P). Accordingly, the present invention discloses a three-dimensional imprinted memory (3D-iP). It uses imprint-lithography to record data into various memory levels. FIG. 4 illustrates a preferred 3D-iP. It uses imprint-lithography to record data. The 3D-iP is a diode-based cross-point memory. It comprises a semiconductor substrate 0 and a 3-D stack 16 stacked above. The 3-D stack 16 comprises M(M≧2) vertically stacked memory levels (e.g. 16A, 16B). Each memory level (e.g. 16A) comprises a plurality of upper address lines (e.g. 2a), lower address lines (e.g. 1a) and memory cells (e.g. 5aa). Each memory cell comprises a diode 3d and stores n (n≧1) bits. Each memory level further comprises at least a data-recording layer, such as an insulating dielectric 87, a resistive layer (referring to U.S. patent application Ser. No. 12/785,621) or an extra-dopant layer (referring to U.S. Pat. No. 7,821,080). Data are recorded into the data-coding layer of the memory levels using imprint-lithography. Memory levels (e.g. 16A, 16B) are coupled to the substrate 0 through contact vias (e.g. 1av, 1av′). The substrate circuit 0X in the substrate 0 comprises a peripheral circuit for the 3-D stack 16.

While illustrative embodiments have been shown and described, it would be apparent to those skilled in the art that many more modifications than that have been mentioned above are possible without departing from the inventive concepts set forth therein. The invention, therefore, is not to be limited except in the spirit of the appended claims.

What is claimed is:

1. A method of manufacturing an imprinted memory, comprising the steps of:
1) forming a plurality of bottom address lines;
2) forming a data-coding layer above said bottom address lines;
3) transferring a data-pattern to said data-coding layer using imprint-lithography;
4) forming a plurality of top address lines above said data-coding layer;
wherein said data-pattern represents the data stored in said imprinted memory; the dimension of said data-pattern is less than 50 nm; and, said data-pattern is a non-periodic pattern.

2. The method according to claim 1, wherein said imprinted memory is a cross-point memory.

3. The method according to claim 1, where said imprinted memory is a three-dimensional imprinted memory (3D-iP).

4. The memory according to claim 1, wherein said imprint-lithography is nanoimprint lithography (NIL).

5. The method according to claim 4, wherein said imprint-lithography is thermoplastic-NIL.

6. The method according to claim 4, wherein said imprint-lithography is photo-NIL.

7. The method according to claim 4, wherein said imprint-lithography is resist-free direct thermal-NIL.

8. The method according to claim 4, wherein said imprint-lithography is electro-chemical NIL.

9. The method according to claim 4, wherein said imprint-lithography is laser-assisted direct imprint-lithography.

10. The method according to claim 1, wherein said imprint-lithography uses full-wafer imprint or step-and-repeat imprint.

11. An imprinted memory, comprising:
a plurality of bottom address lines;
a data-coding layer above said bottom address lines, wherein said data-coding layer comprising a data-pattern formed by imprint-lithography;
a plurality of top address lines above said data-coding layer;
wherein said data-pattern represents the data stored in said imprinted memory; the dimension of said data-pattern is less than 50 nm; and, said data-pattern is a non-periodic pattern.

12. The memory according to claim 11, wherein said imprinted memory is a cross-point memory.

13. The memory according to claim 11, where said imprinted memory is a three-dimensional imprinted memory (3D-iP).

14. The memory according to claim 11, wherein said imprint-lithography is nanoimprint lithography (NIL).

15. The memory according to claim 14, wherein said imprint-lithography is thermoplastic-NIL.

16. The memory according to claim 14, wherein said imprint-lithography is photo-NIL.

17. The memory according to claim 14, wherein said imprint-lithography is resist-free direct thermal-NIL.

18. The memory according to claim 14, wherein said imprint-lithography is electro-chemical NIL.

19. The memory according to claim 14, wherein said imprint-lithography is laser-assisted direct imprint-lithography.

20. The memory according to claim 11, wherein said imprint-lithography uses full-wafer imprint or step-and-repeat imprint.
